(19) United States
(12) Patent Application Publication
(10) Pub. No.: US 2009/0237394 A1
(43) Pub. Date: Sep. 24, 2009

(54) Display driving circuit including output circuit having test circuit and test method thereof

(75) Inventors: Ichirou Matsumoto, Shiga (JP); Satoru Matsuda, Shiga (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/382,601

(22) Filed: Mar. 19, 2009

(30) Foreign Application Priority Data
Mar. 21, 2008 (JP) 2008-074193

(51) Int. Cl. G09G 5/00; G01R 19/00

(52) U.S. Cl. 345/214; 324/76.11

(57) ABSTRACT

A display driving circuit includes an amplifier circuit including an output stage including first and second MOS transistors which are complementary to each other to perform a push-pull operation, an output terminal, a switch element provided between an output end of the output stage and the output terminal, and a controller which enables the first and second MOS transistors to exclusively turn on and off.

### BACKGROUND OF THE INVENTION

1. Field of the Invention

The present invention relates to a display unit-driving circuit and a method for testing the driving circuit and, more particularly, to a driving circuit provided with a circuit for testing the output section thereof and a method for testing the driving circuit.

2. Description of Related Art

In recent years, there has been progress in the effort to expand the scale of gradation, increase the number of outputs, enhance the degree of miniaturization and narrow down pitches also in display panel-driving devices, along with an increase in the definition and size of display panels, such as an LCD. Under these circumstances, cost competition is fierce and a reduction in measurement time involved in the inspection of display panel-driving devices has become an important technical issue. In a display unit-driving circuit, testing the output stage of the driving circuit is especially important. Patent Document 1 discloses a liquid crystal-driving integrated circuit element capable of precisely measuring a leakage current between output-side electrodes or between output-side leads. This element includes an analog switch provided between an operational amplifier serving as an output circuit and an output-side electrode, thereby making it possible to control the analog switch to a high-impedance state when a leakage current between output-side electrodes and/or between output-side leads connected to the output-side electrodes is measured. Consequently, it is possible to precisely measure the leakage current independent of the operational amplifier, thereby making it easy to conduct data analysis intended to reduce leakage current failure.

Note that as the above-described operational amplifier, there is used a loopback cascode type differential amplifier circuit or the like, the input stage of which has a rail-to-rail structure so that the amplifier circuit operates at low voltages and can have a high gain. Such a differential amplifier circuit as mentioned above is described in, for example, Patent Documents 2 and 3.

[Patent Document 1] Japanese Patent Laid-Open No. 2000-066641

[Patent Document 2] Japanese Patent Laid-Open No. 06-326529

[Patent Document 3] Japanese Patent Laid-Open No. 2006-94533

### SUMMARY

The following analysis is given by the present invention.

Not only the measurement of leakage currents between output-side electrodes and between output-side leads but also the measurement of leakage in an output switch (analog switch), leakage in a phase-compensating capacitive element in an amplifier circuit section, and the like has become important. In this case, there is a demand for even stricter measurement conditions in the maximum allowable voltage range as technical requirements for leakage measurement. This is because the measurement conditions lead to an improvement in the accuracy of leakage current detection.

Note here that in the leakage measurement of an analog switch (output switch), the voltage setting of the analog switch solely depends on the voltage setting of an operational amplifier provided according to a D/A converter. Consequently, as the leakage measurement of the analog switch, it is not possible to perform measurement under an even stricter voltage condition. In addition, the measurement must be carried out by setting the output voltage of the D/A converter to a maximum or minimum value. Consequently, a prolonged period of time is consumed in condition setting necessary to provide the D/A converter with data. Thus, a measurement time becomes longer with an increase in the number of analog switches along with an increase in the number of outputs.

Furthermore, there is a need for setting intended to fix the potential of one end of the capacitive element, in order to measure leakage in the phase-compensating capacitive element. In this case, the leakage measurement must be performed for each output terminal, thus requiring a prolonged period of time in measurement.

A display unit-driving circuit in accordance with one exemplary aspect of the present invention comprises, an amplifier circuit configured with mutually complementary first and second MOS transistors, the output stage of which is connected so as to perform push-pull operation, an output terminal, a switch element provided between the output end of the output stage and the output terminal, and a controller for enabling the first and second MOS transistors to exclusively turn on and off.

According to the exemplary aspect of the present invention, it is possible to perform a leakage current measurement on the output section of a driving circuit with precision and in a short period of time.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 is a circuit diagram of the principal part of a driving circuit in accordance with an exemplary embodiment of the present invention;

FIG. 2 is a diagram showing a connection state of external devices at the time of testing the driving circuit; and

FIG. 3 is a flowchart showing a method for testing the driving circuit.

### DETAILED DESCRIPTION OF THE EXEMPLARY EMBODIMENTS

A display unit-driving circuit in accordance with an exemplary embodiment of the present invention is provided with an amplifier circuit, an output terminal, a switch element and a setting means (controller). The amplifier circuit is configured with mutually complementary first and second MOS transistors, the output stage of which is connected so as to perform push-pull operation. The switch element is provided between the output end and the output terminal of an output stage. The setting means (controller) enables the first and second MOS transistors to exclusively turn on and off at the time of testing, in order to test the output stage of the driving circuit.

In the driving circuit of the present invention, the controller is provided with third to sixth MOS transistors each of which is made activatable at the time of testing the driving circuit. The third MOS transistor is capable of driving the first MOS transistor so as to turn off the first MOS transistor. The fourth MOS transistor is capable of driving the second MOS transistor so as to turn on the second MOS transistor. The fifth MOS transistor is capable of driving the first MOS transistor so as to turn on the first MOS transistor. The sixth MOS transistor is capable of driving the second MOS transistor so as to turn off the second MOS transistor.

It is preferable that the driving circuit of the present invention further includes: phase-compensating first and second capacitive elements respectively corresponding to the push and pull sides of push-pull operation located between the output end of the output stage and an internal circuit; a first connection means for enabling the internal circuit connection side of the first capacitive element to connect to a first power supply; and a second connection means for enabling the internal circuit connection side of the second capacitive element to connect to a second power supply.

In the driving circuit of the present invention, the first connection means is a seventh MOS transistor connected between the internal circuit connection side of the first capacitive element and the first power supply. The second connection means is an eighth MOS transistor connected between the internal circuit connection side of the second capacitive element and the second power supply. The seventh and eighth MOS transistors are preferably made activatable at the time of testing the driving circuit.

A method for testing the driving circuit configured as described above includes the steps of: turning off the switch element; turning on one of the first and second MOS transistors and turning off the other one thereof; supplying a second power supply voltage to the output terminal if a first power supply voltage arises in the output end of an output stage as a result of one of the first and second MOS transistors being turned on; and detecting a first current flowing through the output terminal.

In addition, the test method may further include the steps of: turning on one of the first and second MOS transistors and turning off the other one thereof; supplying a first power supply voltage to the output terminal if a second power supply voltage arises in the output end of the output stage as a result of the other one of the first and second MOS transistors being turned on; and detecting a second current flowing through the output terminal.

Furthermore, the test method may include the steps of: connecting the internal circuit connection side of the first capacitive element to the first power supply; and detecting a current flowing from the first power supply to the driving circuit.

Still further, the test method may further include the steps of: disconnecting the internal circuit connection side of the first capacitive element from the first power supply; connecting the internal circuit connection side of the second capacitive element to the second power supply; and detecting a current flowing from the first power supply to the driving circuit.

According to such a test of the display unit-driving circuit as described above, it is possible to apply a power supply voltage and a GND voltage to one and the other end of the output switch. Thus, it is possible to set a large potential difference, thereby improving the accuracy of leakage current measurement. In addition, since the test method includes a selector switch in the output stage, it is possible to switch test conditions in a short period of time using an external input signal. Furthermore, it is possible to simultaneously carry out the measurement of static current consumption and the measurement of leakage in the capacitive element in the output stage, thereby shortening a measurement time.

### Exemplary Embodiment

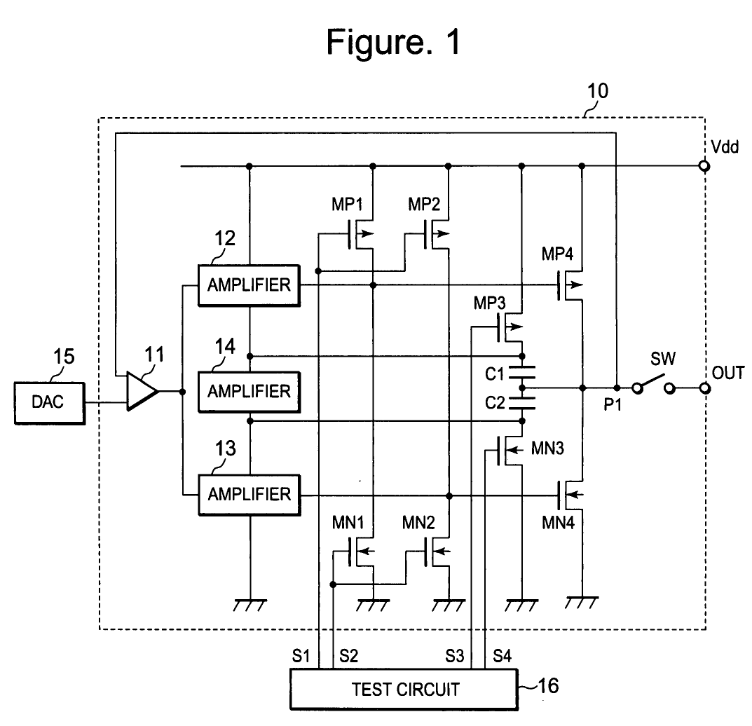

FIG. 1 is a circuit diagram of the principal part of a driving circuit in accordance with an exemplary embodiment of the present invention. In FIG. 1, the driving circuit is a circuit for driving a data line, in order to supply data to the TFTs of a liquid crystal panel. The driving circuit includes, in the principal part thereof, a D/A converter 15, an output circuit 10, an output end OUT, and a test circuit 16. The D/A converter 15 D/A-converts a data signal and outputs the data signal to the output circuit 10. The output circuit 10 is provided with amplifier circuits 11, 12, 13 and 14, NMOS transistors MN1 to MN4, PMOS transistors MP1 to MP4, capacitive elements C1 and C2, and an output switch SW configured with a transfer gate or the like. The amplifier circuit 11 corresponds to the input stage of a loopback cascode type differential amplifier circuit having a rail-to-rail structure and provides the output signal of the D/A converter 15 to the amplifier circuits 12 and 13. The amplifier circuit 12 amplifies the output signal of the D/A converter 15 to drive the gate of the PMOS transistor MP4. The amplifier circuit 13 amplifies the output signal of the D/A converter 15 to drive the gate of the NMOS transistor MN4. The amplifier circuit 14 controls the idling currents of the amplifier circuits 12 and 13 using a voltage input from an internal bias circuit.

The drain of the NMOS transistor MN4, the source of which is grounded, and the drain of the PMOS transistor MP4, the source of which is connected to a power supply Vdd, are commonly connected to the inverting input terminal of the amplifier circuit 11, one end of the output switch SW, one end of the capacitive element C1, and one end of the capacitive element C2. The other end of the capacitive element C1 is connected to a connection point between the amplifier circuits 12 and 14 and functions as a phase compensator for preventing oscillation. In addition, the other end of the capacitive element C2 is connected to a connection point between the amplifier circuits 13 and 14 and functions as a phase compensator for preventing oscillation. The NMOS transistor MN4 and the PMOS transistor MP4 constitute an output stage having a complementary push-pull structure. The other end of the output switch SW is connected to the output end OUT.

The source of the PMOS transistor MP1 is connected to the power supply Vdd, the drain thereof is connected to the gate of the PMOS transistor MP4, and the gate thereof is provided with a signal S1 from the test circuit 16. The source of the PMOS transistor MP2 is connected to the power supply Vdd, the drain thereof is connected to the gate of the NMOS transistor MN4, and the gate thereof is provided with the signal S1 from the test circuit 16. The source of the PMOS transistor MP3 is connected to the power supply Vdd, the drain thereof is connected to the other end of the capacitive element C1, and the gate thereof is provided with a signal S3 from the test circuit 16.

The source of the NMOS transistor MN1 is grounded, the drain thereof is connected to the gate of the PMOS transistor MP4, and the gate thereof is provided with a signal S2 from the test circuit 16. The source of the NMOS transistor MN2 is grounded, the drain thereof is connected to the gate of the NMOS transistor MN4, and the gate thereof is provided with the signal S2 from the test circuit 16. The source of the NMOS transistor MN3 is grounded, the drain thereof is connected to the other end of the capacitive element C2, and the gate thereof is provided with a signal S4 from the test circuit 16.

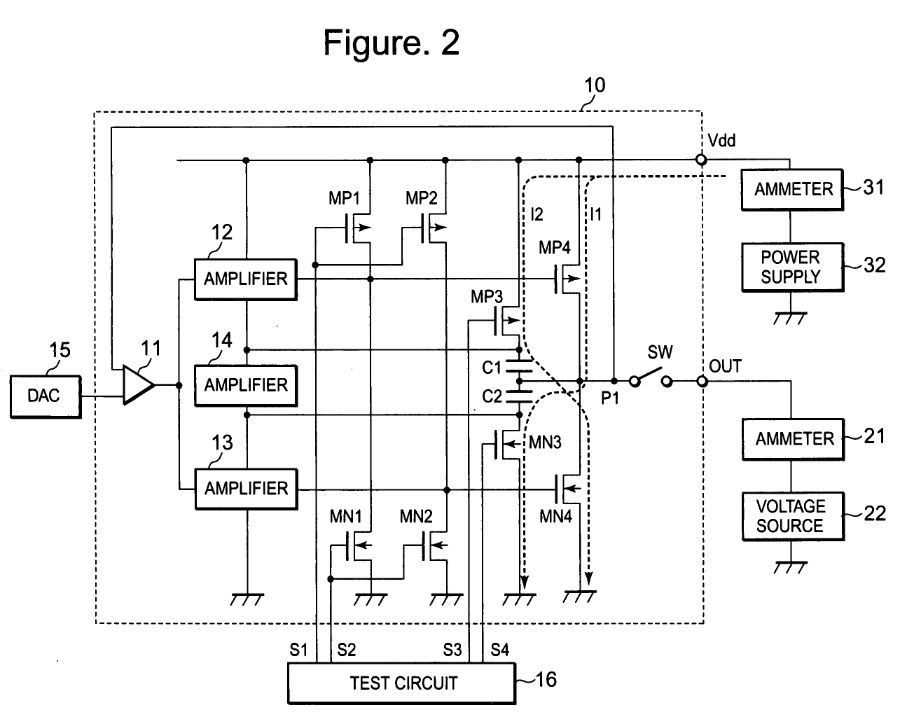

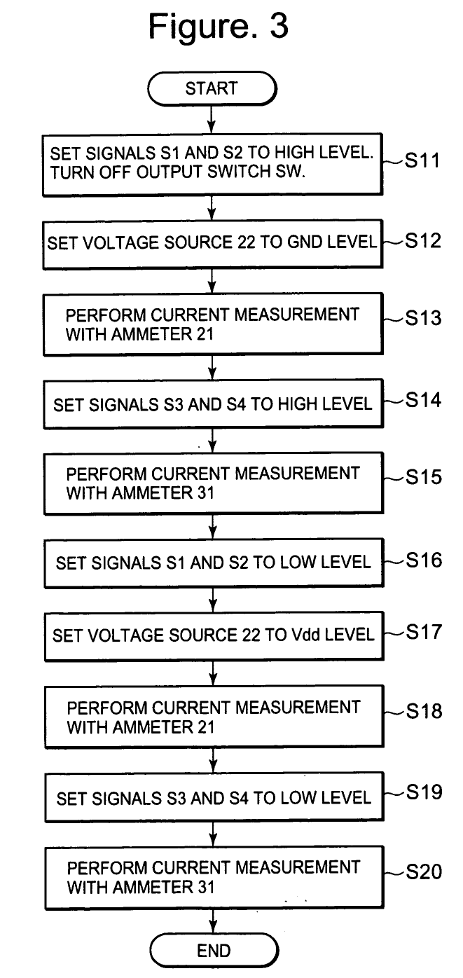

Next, an explanation will be made of a method for testing the driving circuit configured as described above. FIG. 2 is a diagram showing a connection state of external devices at the time of testing the driving circuit. In FIG. 2, reference symbols the same as those of FIG. 1 denote one and the same components and will not be explained again. Power is supplied to the power supply Vdd of the driving circuit from a power supply 32 through an ammeter 31. In addition, a voltage source 22 is connected to the output terminal OUT through an ammeter 21. FIG. 3 is a flowchart showing a method for testing the driving circuit.

First, there is performed a first leak measurement on the output switch SW. The signals S1 and S2 of the test circuit 16 are set to a high level. Thus, the PMOS transistors MP1 and MP2 turn off and the NMOS transistors MN1 and MN2 turn on. Consequently, the PMOS transistor MP4 in the output stage turns on and the NMOS transistor MN4 therein turns off. At this time, the voltage of an output end P1 in the output stage equals the voltage of the power supply Vdd. In addition, the output switch SW is set to an OFF state (open) (step S11).

Under this condition, a GND (ground)-side voltage is applied to the output end OUT by the voltage source 22 (step S12). As a result, the voltage of the power supply Vdd is applied across the output switch SW in an OFF state. Thus, it is possible to detect leakage in the output switch SW by measuring the current thereof with the ammeter 21 (step S13).

Next, the leakage measurement of the capacitive element C2 is performed. Under the above-described respective conditions of switch setting, the test circuit 16 sets the signals S3 and S4 to a high level (step S14). Thus, the PMOS transistor MP3 turns off and the NMOS transistor MN3 turns on. Under this condition, a current (“I1” in FIG. 2) flows between the power supply Vdd and the GND by way of the PMOS transistor MP4, the capacitive element C2 and the NMOS transistor MN3, if leakage occurs. Thus, it is possible to detect leakage in the capacitive element C2 by measuring a power supply current (more precisely, an incremental current generated from the moment the NMOS transistor MN3 turns off) with the ammeter 31 (step S15).

In addition, the second leakage measurement of the output switch SW is performed. The test circuit 16 sets the signals S1 and S2 to a low level (step S16). Thus, the PMOS transistors MP1 and MP2 turn on and the NMOS transistors MN1 and MN2 turn off. Consequently, the PMOS transistor MP4 in the output stage turns off and the NMOS transistor MN4 therein turns on. At this time, the output end P1 of the output stage is set to a ground voltage. In addition, the output switch SW is set to an OFF state.

Under this condition, a power supply side voltage is applied to the output end OUT by the voltage source 22 (step S17). As a result, the voltage of the power supply Vdd is applied across the output switch SW in an OFF state. Thus, it is possible to detect leakage in the output switch SW by measuring the current thereof with the ammeter 21 (step S18).

Next, the leakage measurement of the capacitive element C1 is performed. Under the above-described respective conditions of switch setting, the test circuit 16 sets the signals S3 and S4 to a low level (step S19). Thus, the PMOS transistor MP3 turns on and the NMOS transistor MN3 turns off. Under this condition, a current (“I2” in FIG. 2) flows between the power supply Vdd and the GND by way of the PMOS transistor MP3, the capacitive element C1 and the NMOS transistor MN4, if leakage occurs. Thus, it is possible to detect leakage in the capacitive element C1 by measuring a power supply current (more precisely, an incremental current generated from the moment the PMOS transistor MP3 turns off) with the ammeter 31 (step S20).

As described above, the driving circuit is provided with the PMOS transistors MP1 and MP2 and the NMOS transistors MN1 and MN2 which function as selector switches in the output stage of the output circuit 10. The voltage of the power supply Vdd or the GND voltage is applied to one end (P1) of the output switch SW by turning the PMOS transistor MP4 and the NMOS transistor MN4 on and off. A voltage opposite to the voltage applied to the one end of the output switch SW is applied to the other end (output end OUT side) of the output switch SW from the outside. By supplying voltages in this way, it is possible to increase a potential difference across the output switch SW. Consequently, it is possible to improve the accuracy of leakage measurement performed on the output switch SW.

In addition, a period of time taken to set a measurement condition is shortened, compared with a case in which leakage measurement is performed by setting the output voltage of the D/A converter 15 to a maximum or minimum value, since the output stage of the output circuit 10 is switched using the test circuit 16.

Furthermore, it is possible to measure static current consumption concurrently with the detection of leakage in a capacitive element by turning on and off the PMOS transistor MP3 and the NMOS transistor MN3 associated with the PMOS transistor MP4, the NMOS transistor MN4, and the capacitive elements C1 and C2 under the above-described condition, using the test circuit 16. Thus, a measurement time involved in tests is shortened. That is, if there is leakage in the capacitive element C1 or C2, the capacitive leakage can be detected in the form of a current added to the static current consumption. Accordingly, it is possible to promptly perform the leakage measurement of the capacitive elements at the time of measuring the static current consumption.

It should be noted that the respective disclosures of the aforementioned patent documents and the like are incorporated herein by reference. The exemplary embodiments and the examples described herein may be altered or adjusted within the framework of the entire disclosure of the present invention (including the claims) and in accordance with the fundamental technical idea thereof. In addition, a diverse combination or selection of various disclosed elements is possible within the framework of the claims for the present invention. Namely, it is needless to say that the present invention includes various alterations and modifications that those skilled in the art would be able to make according to the entire disclosure, including the claims, and to the technical idea.

Further, it is noted that Applicant's intent is to encompass equivalents of all claim elements, even if amended later during prosecution.

What is claimed is:

1. A display driving circuit, comprising:
an amplifier circuit including an output stage comprising first and second MOS transistors which are complementary to each other to perform a push-pull operation;
an output terminal;
a switch element provided between an output end of said output stage and said output terminal; and
a controller which enables said first and second MOS transistors to exclusively turn on and off.

2. The display driving circuit according to claim 1,
wherein said controller includes third to sixth MOS transistors which are activated at a time of testing said driving circuit,
wherein said third MOS transistor is capable of driving said first MOS transistor so as to turn off said first MOS transistor,
wherein said fourth MOS transistor is capable of driving said second MOS transistor so as to turn on said second MOS transistor,
wherein said fifth MOS transistor is capable of driving said first MOS transistor so as to turn on said first MOS transistor, and
wherein said sixth MOS transistor is capable of driving said second MOS transistor so as to turn off said second MOS transistor.

3. The display driving circuit according to claim 1, further including:
first and second capacitive elements, respectively corresponding to push and pull sides of said push-pull operation, located between the output end of said output stage and an internal circuit for phase-compensation;
a first connection circuit to enable an internal circuit connection side of said first capacitive element to connect to a first power supply; and
a second connection circuit to enable the internal circuit connection side of said second capacitive element to connect to a second power supply.

4. The display driving circuit according to claim 3, wherein
said first connection circuit includes a seventh MOS transistor connected between said first capacitive element and said first power supply,
said second connection circuit includes an eighth MOS transistor connected between said second capacitive element and said second power supply, and
said seventh and eighth MOS transistors are activated at a time of testing said driving circuit.

5. A method of testing a display unit-driving circuit, said circuit comprising
an amplifier circuit including an output stage comprising first and second MOS transistors which are complementary to each other to perform a push-pull operation;
an output terminal; and
a switch element provided between an output end of said output stage and said output terminal,
the method comprising:
turning off said switch element;
turning on one of said first and second MOS transistors and turning off the other one thereof;
supplying a second power supply voltage to said output terminal when a first power supply voltage arises in the output end of said output stage as a result of one of said first and second MOS transistors being turned on; and
detecting a first current flowing through said output terminal.

6. The method according to claim 5, further including:
supplying said first power supply voltage to said output terminal when said second power supply voltage arises in the output end of said output stage as a result of the other one of said first and second MOS transistors being turned on; and
detecting a second current flowing through said output terminal.

7. The method according to claim 5,
wherein said driving circuit comprises first and second capacitive elements, respectively corresponding to push and pull sides of said push-pull operation, located between said output end of said output stage and an internal circuit,
the method further including:
connecting said first capacitive element to said first power supply; and
detecting a current flowing from said first power supply to said driving circuit.

8. The method according to claim 7, further including:
disconnecting said first capacitive element from said first power supply;
connecting an internal circuit connection side of said second capacitive element to said second power supply; and
detecting a current flowing from said first power supply to said driving circuit.

9. A display driving circuit, comprising:
a first transistor of a first conductivity type coupled between a first power source line and a first node;
a second transistor of a second conductivity type coupled between the first node and a second power source line;
a first driver which drives the first transistor;
a second driver which drives the second transistor;
a switch coupled between the first node and an output terminal;
a third transistor coupled between the first power source line and a second node and receiving a first test signal;
a first capacitor coupled between the second node and the first node;
a second capacitor coupled between the first node and a third node;
a fourth transistor coupled between the third node and the second power source line and receiving a second test signal;
a fifth transistor coupled between the first power source line and a control gate of the second transistor and receiving a third test signal;
a sixth transistor coupled between the control gate of the second transistor and the second power source line and receiving a fourth test signal;
a seventh transistor coupled between the first power source line and a control gate of the first transistor and receiving the third test signal; and
an eighth transistor coupled between the control gate of the first transistor and the second power source line and receiving the fourth test signal.
